(19) United States
(12) Patent Application Publication
(10) Pub. No.: US 2008/0122474 A1
(43) Pub. Date: May 29, 2008

(54) SYSTEMS AND METHODS FOR REDUCING THE EFFECTS OF ELECTROSTATIC DISCHARGE

(75) Inventors: Che Choi C. Leung, Bethlehem, PA (US); Richard J. Niescier, Bethlehem, PA (US); Yehuda Smooha, Allentown, PA (US)

Correspondence Address: HAMILTON AND DESANCTIS, 8555 W. BELLEVIEW AVE., LITTLETON, CO, 80123, US

(73) Assignee: Agere Systems Inc.

(21) Appl. No.: 11/563,264

(22) Filed: Nov. 27, 2006

(51) Int. Cl. G01R 31/26; H02H 9/00

(52) U.S. Cl. 324/765; 361/56

(57) ABSTRACT

Various systems and methods for limiting the effects of electrostatic discharge are disclosed. For example, a system for reducing the effects of electrostatic discharge is disclosed that includes at least two isolated pairs of potential planes. The two isolated pairs of potential planes may include, but are not limited to, a first VDD plane paired with a first VSS plane may be isolated from a second VDD plane that is paired with a second VSS plane. One circuit in the system is powered by a differential between one pair of the potential planes, and another circuit is powered by a differential between the other pair of potential planes. In addition, the system includes a transitional circuit that receives a signal output from the first of the aforementioned circuits, and provides a signal input to the second of the aforementioned circuits. The transitional circuit is powered by a differential between one potential plane from one of the pairs of potential planes, and one potential plane from another of the pairs of potential planes.

### BACKGROUND OF THE INVENTION

The present invention is related to reducing the effects of electrostatic discharge, and more particularly, to systems and methods that limit the effects of electrostatic discharge.

Electrostatic discharge involves the sudden transfer of charge between bodies that is caused by the different potentials of the bodies. In some cases, the aforementioned electrostatic discharge involves passing current across the gate oxide of one or more transistor devices. FIG. 1 shows an exemplary circuit 100 including transistors 165, 166 powered by a potential plane 110 (VDD1) and a potential plane 140 (VSS1), and transistors 155, 156 powered by a potential plane 120 (VDD2) and a potential plane 130 (VSS2). As an example, when the potential on potential plane 130 becomes substantially higher than the potential on potential plane 110, an electrostatic discharge along a current path 170 may occur. As shown, current path 170 traverses the gate oxide of transistor 155, thereby damaging transistor 155.

One or more tests may be employed to determine a semiconductor device's susceptibility to electrostatic discharge. For example, a Field-Induced Charged-Device Model Test, or simply Charged Device Model (CDM) Test may be used to test a semiconductor device. This test involves placing a semiconductor device in a magnetic field that induces a several hundred volt potential on nodes of the semiconductor device. Once the voltage potential is induced on the nodes of the semiconductor device, a particular pin of the semiconductor device is grounded. The combination of the potential at the nodes and the grounded pin causes an electrostatic discharge, and it is determined whether the electrostatic discharge resulted in damage to the semiconductor device.

One or more circuit approaches have been developed to limit the possibility of electrostatic discharge traversing the gate oxide of transistor 155 when the semiconductor device is exposed to CDM testing. For example, as shown in FIG. 2, a transistor 220 and a resistor 210 may be added to the circuit of FIG. 1 to reduce the possibility of damaging transistor 155 via the previously discussed electrostatic discharge path. In this case, where the potential at potential plane 130 becomes much greater than that at potential plane 110, the electrostatic discharge path traverses transistor 220 rather than the gate oxide of transistor 155. While this additional circuitry offers reasonable protection from electrostatic discharge, the cost in terms of area may be very significant where a number of inter-domain signals are to be protected each using a transistor 220. Further, the combination of the capacitance of transistor 220 and the resistance of resistor 210 may distort or delay the signal applied to the gates of transistors 155, 156. This delay may limit the operational capability of the overall circuit.

Another approach for limiting the possibility of electrostatic discharge traversing the gate oxide of transistor 155 when the semiconductor device is exposed to CDM testing is shown as a circuit 300 of FIG. 3. In circuit 300, a coupling circuit 310 is used to electrically connect isolated potential planes 130, 140. Coupling circuit 310 includes a pair of back-to-back diodes 340, 350 coupled on one end to potential plane 140 via a resistance 330 and on the other end to potential plane 130 by a resistance 320. Coupling circuit 310 provides a discharge path between potential plane 130 and potential plane 140 through diode 350 as an alternative to any discharge path that traverses the gate oxide of transistor 155. When subjected to a CDM test where a pin associated with potential plane 110 is grounded, a possible electrostatic discharge path 370 exists from potential plane 130 to potential plane 110 via the gate oxide of transistor 155 and the parasitic diode of transistor 166. Thus, where the resistance offered by the gate oxide of transistor 155 and the parasitic diode of transistor 166 is less than other possible discharge paths, circuit 300 may be damaged by current traversing the gate oxide of transistor 155. Thus, for coupling circuit 310 to be effective, the resistance 320, 330 must be very small because only a very small current (e.g., 10 uA) is required to damage the gate oxide of transistor 155. In a semiconductor device of any size, there may be many transistors that are exposed to potential damage of electrostatic discharge (e.g., transistor 155), and coupling circuits protecting each of the aforementioned transistors may be required. Thus, while such an approach may offer some hope of protecting the exposed transistors, even careful floor planning may not allow for sufficiently low resistances 320, 330 to render this type of protection effective.

Hence, for at least the aforementioned reasons, there exists a need in the art for advanced systems and methods for limiting the effects of electrostatic discharge.

### BRIEF SUMMARY OF THE INVENTION

The present invention is related to reducing the effects of electrostatic discharge, and more particularly, to systems and methods that limit the effects of electrostatic discharge.

Various embodiments of the present invention provide systems for reducing the effects of electrostatic discharge. Such systems include at least two isolated pairs of potential planes. Thus, for example, a first VDD plane paired with a first VSS plane may be isolated from a second VDD plane that is paired with a second VSS plane. One circuit in the system is powered by a differential between one pair of the potential planes, and another circuit is powered by a differential between the other pair of potential planes. In addition, the system includes a transitional circuit that receives a signal output from the first of the aforementioned circuits, and provides a signal input to the second of the aforementioned circuits. The transitional circuit is powered by a differential between one potential plane from one of the pairs of potential planes, and one potential plane from the other pair of potential planes.

In some cases of the aforementioned embodiments, the pairs of potential planes each include a power plane and a ground plane, and the transitional circuit is powered by a differential between the power plane of one of the pairs of potential planes, and the ground plane from the other pair of potential planes. In such cases, the two ground planes may be isolated one from another and yet maintained at approximately the same voltage potential when the system is in normal operation. Similarly, the two power planes may be isolated one from another and yet maintained at approximately the same voltage level when the system is in normal operation.

In various cases of the aforementioned embodiments, the pairs of potential planes each include a VDD plane and a VSS plane, and the transitional circuit is powered by a differential between the VDD plane of one of the pairs of potential planes, and the VSS plane from the other pair of potential planes. In such cases, the two VSS planes may be isolated one from another and yet maintained at approximately the same voltage potential when the system is in normal operation. Similarly, the two VDD planes may be isolated one from another and yet maintained at approximately the same voltage level when the system is in normal operation.

In various instances of the aforementioned embodiments, a plane coupling circuit is included between one potential plane from one of the pairs of potential planes, and one potential plane from another of the pairs of potential planes. Thus, for example, a plane coupling circuit may be implemented between the ground plane of one of the pairs of potential planes and the ground plane of another of the pairs of potential planes. Alternatively, or in addition, a plane coupling circuit may be implemented between the power plane of one of the pairs of potential planes and the power plane of another of the pairs of potential planes. In such cases, the two power planes are maintained at approximately the same voltage level when the system is in normal operation, and the two ground planes are maintained at approximately the same voltage level when the system is in normal operation. In some particular cases, the plane coupling circuit includes a pair of back-to-back diodes. In such cases, the system may further include reverse biased diode electrically coupled between the potential planes of one of the pairs of potential planes, and another reverse biased diode electrically coupled between the potential planes of another of the pairs of potential planes.

In one particular instance of the aforementioned embodiments where one pair of the potential planes includes a first VDD plane and a first VSS plane, and the other pair of the potential plane includes a second VDD plane and a second VSS plane, the transitional circuit includes a P-type transistor and an N-type transistor. In such a case, the gate of the P-type transistor and the gate of the N-type transistor are electrically coupled to the signal output. A first input of the P-type transistor is electrically coupled to the second VDD plane, and a second input of the P-type transistor is electrically coupled to a first input of the N-type transistor. A second input of the N-type transistor is electrically coupled to the first VSS plane, and the second input of the P-type transistor and the first input of the N-type transistor are electrically coupled to the signal output. In some such cases, the first VDD plane and the second VDD plane are biased at approximately the same voltage level, and the first VSS plane and the second VSS plane are biased at approximately the same voltage level.

In other instances of the aforementioned embodiments where one pair of the potential planes includes a first VDD plane and a first VSS plane, and the other pair of the potential plane includes a second VDD plane and a second VSS plane, the transitional circuit includes a P-type transistor and an N-type transistor. In such cases, the transitional circuit includes a P-type transistor and an N-type transistor. The gate of the P-type transistor and the gate of the N-type transistor are electrically coupled to the signal output, a first input of the P-type transistor is electrically coupled to the first VDD plane, and a second input of the P-type transistor is electrically coupled to a first input of the N-type transistor. A second input of the N-type transistor is electrically coupled to the second VSS plane, and the second input of the P-type transistor and the first input of the N-type transistor are electrically coupled to the signal output. In some such cases, the first VDD plane and the second VDD plane are biased at approximately the same voltage level, and the first VSS plane and the second VSS plane are biased at approximately the same voltage level.

Other embodiments of the present invention provide methods for electrostatic discharge testing of a semiconductor device. The methods include providing a semiconductor device that has at least a first pin and a second pin. The semiconductor device includes two circuits. One of the circuits is powered by a differential between a first potential plane and a second potential plane, and the other circuit is powered by a differential between a third potential plane and a fourth potential plane. The semiconductor device further includes a transitional circuit that receives a signal output from the first circuit and provides a signal input to the second circuit, and wherein the transitional circuit is powered by a differential between the first power potential and the fourth power potential. The semiconductor device further includes a plane coupling circuit that is electrically coupled between the first potential plane and the third potential plane. In some cases, the plane coupling circuit includes a pair of back-to-back diodes. The semiconductor device further includes a reverse biased diode that is electrically coupled between the first potential plane and the second potential plane. The method further includes inducing a voltage potential on each of the first potential plane, the second potential plane, the third potential plane, and the fourth potential plane; and grounding either of the first pin or the second pin, wherein an electrically conductive path is established between the fourth potential plane and the second potential plane.

In some instances of the aforementioned methods, the methods additionally include failing the semiconductor device where the electrically conductive path includes the signal input, or passing the semiconductor device where the electrically conductive path avoids the signal input. In other instances of the aforementioned methods, the electrically coupled path avoids the signal input, and includes the plane coupling circuit and the reverse biased diode.

Yet other embodiments of the present invention provide electrostatic discharge resistant circuits. Such circuits include a first group of transistors that is powered by a differential between a first potential plane and a second potential plane, and a second group of transistors that is powered by a differential between a third potential plane and a fourth potential plane. In addition, the circuits include a transitional group of transistors that receives a signal output from the first group of transistors and provides a signal input to the second group of transistors, and that is powered by a differential between the first power potential and the fourth power potential. The circuits also include a plane coupling circuit and two reverse biased diodes. One of the reverse biased diodes is electrically coupled between the first potential plane and the second potential plane, and the other reverse biased diode is electrically coupled between the third potential plane and the fourth potential plane. The plane coupling circuit is electrically coupled between one of the pair of the first potential plane and the third potential plane, or the pair of the second potential plane and the fourth potential plane. The plane coupling circuit include a pair of back-to-back diodes.

This summary provides only a general outline of some embodiments according to the present invention. Many other objects, features, advantages and other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several drawings to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 depicts a prior art circuit powered using two power domains;

FIG. 2 depicts another prior art circuit powered using two power domains and incorporating an electrostatic discharge limiting circuit;

FIG. 3 depicts another prior art circuit powered using two power domains and incorporating another electrostatic discharge limiting circuit;

FIG. 4 shows a circuit powered using cross-accessed power domains in accordance with one or more embodiments of the present invention; and

FIGS. 5a-5b show an exemplary circuit powered using cross-accessed power domains in accordance with various embodiments of the present invention; and

FIGS. 6a-6b show another exemplary circuit powered using cross-accessed power domains in accordance with other embodiments of the present invention.

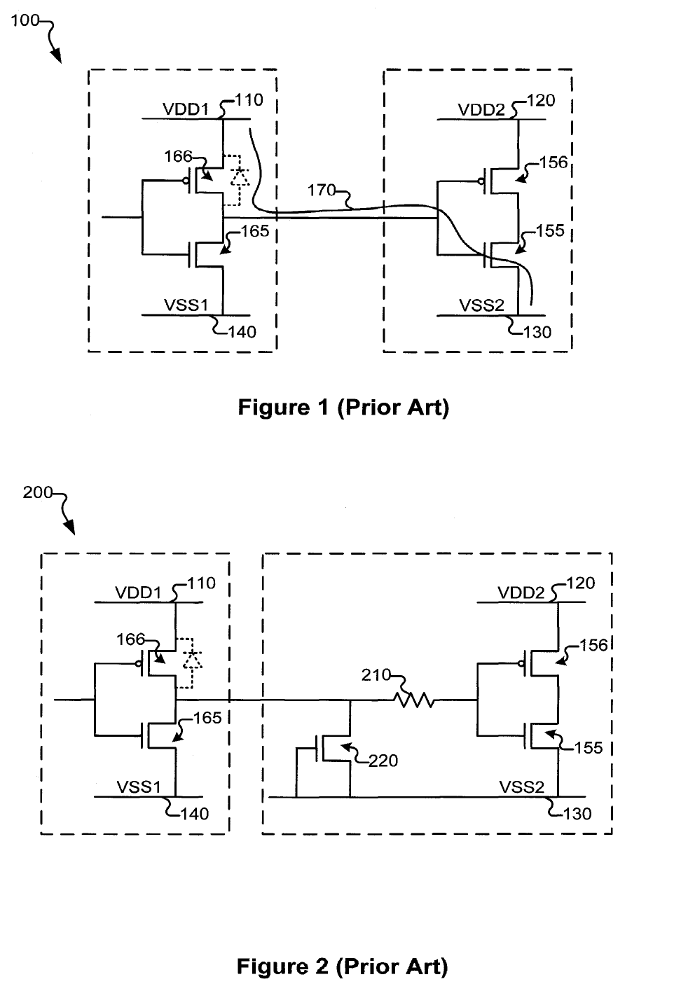

### DETAILED DESCRIPTION OF THE INVENTION

The present invention is related to reducing the effects of electrostatic discharge, and more particularly, to systems and methods that limit the effects of electrostatic discharge.

Turning to FIG. 4, circuit 400 powered using cross-accessed power domains in accordance with one or more embodiments of the present invention is depicted. Circuit 400 includes a drive circuit 410 that is powered by a differential between a pair of potential planes, including potential plane 460 and a potential plane 466. As shown, when circuit 400 is operational, potential plane 460 is driven to a voltage level A and potential plane 466 is driven to a voltage level B. Circuit 400 also includes a receive circuit 420 that is powered by a differential between a pair of potential planes, including a potential plane 462 and a potential plane 464. When circuit 400 is operational, potential plane 462 is driven to a voltage level C and potential plane 464 is driven to a voltage level D. Circuit 400 also includes a transitional circuit 430 that is powered by a differential between potential plane 462 and potential plane 464. Each of the pairs of potential planes (i.e., potential planes 460, 466 and potential planes 462, 464) are referred to herein as domains. Thus, an inter domain signal is a signal that is driven by a circuit powered by one domain, and received by a circuit powered by another domain.

Drive circuit 410 drives a signal output 480 to transitional circuit 430, and transitional circuit 430 drives a signal input 490 to receive circuit 420. In this way, inter-domain signaling from drive circuit 410 to receive circuit 420 is electrically coupled via transitional circuit 430 that cross-accesses potential planes. Thus, an inter domain signal that would have traditionally been connected directly between drive circuit 410 and receive circuit 420 is connected by a transitional circuit 430 that is cross-domain (i.e., a circuit that is powered by one potential plane from one domain, and another potential plane in another domain).

Circuit 400 further includes at least one plane coupling circuit 440 that electrically couples either potential plane 464 to potential plane 466, and/or potential plane 460 to potential plane 462. Plane coupling circuit 440 along with transitional circuit 430 limits the possibility that an electrostatic discharge will create a current path passing through the gate oxide of one or more transistors in drive circuit 410 or receive circuit 420. In some cases, plane coupling circuit 440 is comprised of back-to-back diodes. In some embodiments of the present invention, voltage level A and voltage level C are approximately the same voltage level, and voltage level B and voltage level D are approximately the same voltage level. In various embodiments of the present invention, voltage level B is greater than voltage level A and voltage level D is greater than voltage level C, while in other embodiments of the present invention voltage level A is greater than voltage level B and voltage level C is greater than voltage level D. In one particular embodiment of the present invention, both voltage level A and voltage level C are maintained at approximately the same non-zero voltage level, and voltage level B and voltage level D are maintained at approximately ground.

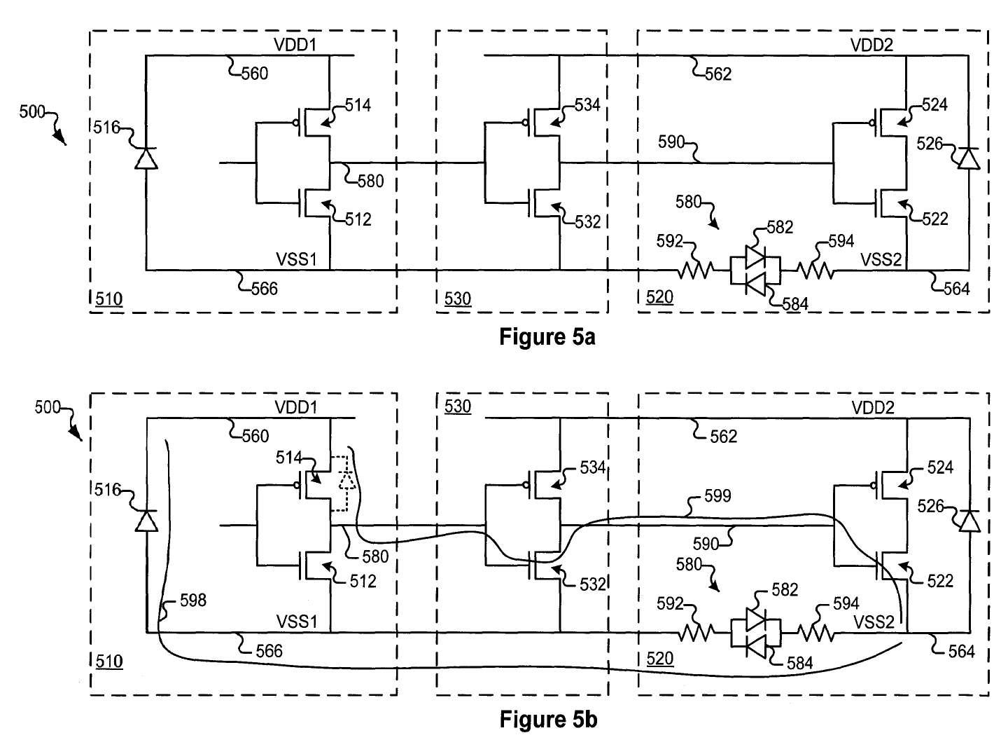

Turning to FIG. 5, an exemplary circuit 500 powered using cross-accessed power domains in accordance with various embodiments of the present invention is depicted. In particular, circuit 500 includes a drive circuit 510 that is powered by a differential between a pair of potential planes, including a VDD1 plane 560 and a VSS1 plane 566. As shown, when circuit 500 is operational, potential plane 560 is driven to a voltage level defined as VDD and potential plane 566 is driven to a voltage level defined as VSS. Circuit 500 also includes a receive circuit 520 that is powered by a differential between a pair of potential planes, including a VDD2 plane 562 and a VSS2 plane 564. Potential plane 562 is driven to a voltage level defined as VDD and potential plane 564 is driven to a voltage level defined as VSS. Circuit 500 also includes a transitional circuit 530 that is powered by a differential between potential plane 562 and potential plane 566. Each of the pairs of potential planes (i.e., VSS1/VDD1 and VSS2/VDD2) are referred to as domains.

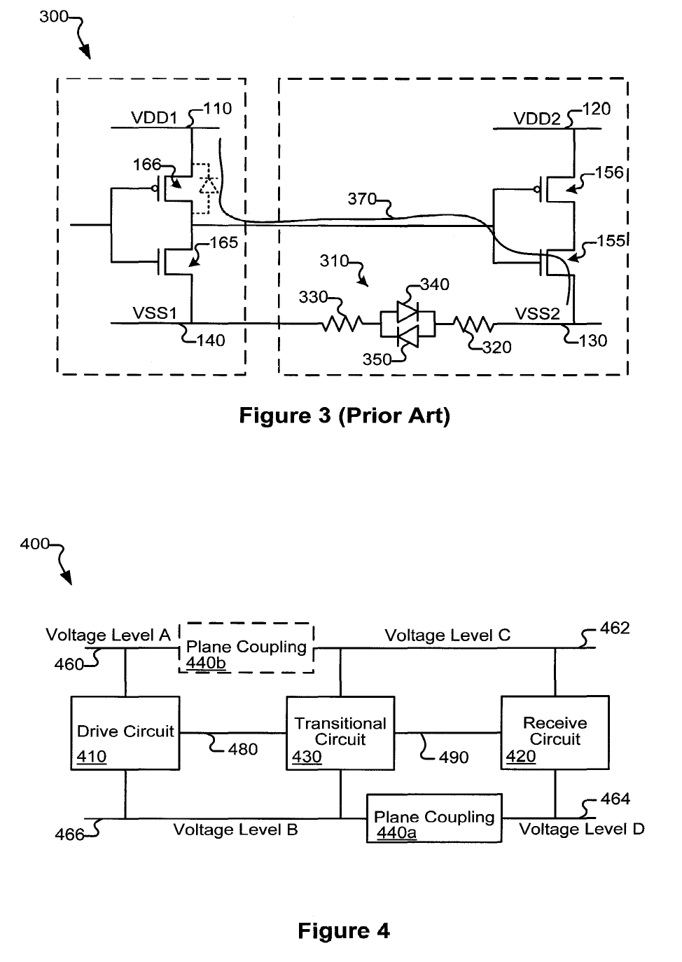

Drive circuit 510 drives a signal output 580 to transitional circuit 530, and transitional circuit 530 drives a signal input 590 to receive circuit 520. In this way, inter-domain signaling from drive circuit 510 to receive circuit 520 is electrically coupled via transitional circuit 530 that cross-accesses the potential planes. Thus, an inter domain signal that would have traditionally been connected directly between drive circuit 510 and receive circuit 520 (see e.g., FIG. 3 above) is connected by a transitional circuit 530 that is cross-domain (i.e., a circuit that is powered by one potential plane from one domain, and another potential plane in another domain).

Circuit 500 further includes a plane coupling circuit 580 that electrically couples VSS1 plane 566 to VSS2 plane 564. As shown, plane coupling circuit 580 includes back-to-back diodes 582, 584 and resistances 592, 594. In most cases, resistances 592, 594 represent the routing resistance and are modifiable by adjusting any floor planning that is done in the layout of circuit 500. It should be noted that in some cases a circuit similar to plane coupling circuit 580 may be used to couple VDD1 plane 560 to VDD2 plane 562 either in addition to plane coupling circuit 580 or in place of plane coupling circuit 580.

FIG. 5b shows two possible paths 598, 599 through which an electrostatic discharge may take place when a pin associated with VDD1 plane 560 is grounded after a voltage is induced on nodes of circuit 500 during a CDM test. Path 598 moves current from VSS2 plane 564 to VDD1 plane 560 via resistances 592, 594, back-to-back diode 584 and diode 516, which is in reverse bias during normal operation of circuit 500. Diode 516 may be referred to as “reverse bias diode” 516. As used herein, the phrase “reverse bias diode” indicates the bias on the diode when the associated circuit is in normal operation and does not indicate a bias relative to an electrostatic discharge path. In contrast, path 599 moves current from VSS2 plane 564 to VDD1 plane 560 via the gate oxide of transistor 522, the gate oxide of transistor 532, and the parasitic diode of transistor 514. As will be appreciated by one of ordinary skill in the art, passing current along path 599 results in damage to circuit 500, while passing a reasonable current along path 598 does not result in damage to circuit 500. Where the effective resistance of path 598 is less than that of path 599, circuit 500 is protected from damage. In this case, the effective resistance of each of the paths is set forth in the following equations:

R_{Path 598}=R₅₉₂+R₅₉₄+R_{Diode 584}+R_{Diode 516}, where R₅₉₂+R₅₉₄ represents all routing resistance along path 598; and

R_{Path 599}=R_{Gate Oxide 522}+R_{Gate Oxide 532}+R_{Diode 514}+R_{Routing}, where R_{Routing} represents all routing resistance along path 599; and

Path 599 stands in contrast to electrostatic discharge path 370 of FIG. 3 where the resistance path includes only a single gate oxide (i.e., the gate oxide of transistor 155). The additional resistance of the gate oxide of transistor 532 of path 599 makes the destructive current path 599 less likely than the previously described path 370. The additional resistance exhibited by path 599 (i.e., the resistance associated with traversing the gate oxide of transistor 532) offers greater design margin. Where in circuit 300 resistances 320, 330 had to be very carefully controlled to avoid enabling path 370, in circuit 500 the combination of resistances 592, 594 may be increased by an amount approximately equal to the resistance of the gate oxide of transistor 532 without enabling path 599.

In some cases, when circuit 500 is operational (i.e., powered in a normal operational mode), VDD1 is maintained to a voltage potential that is approximately the same as VDD2. Similarly, VSS1 may be maintained at the same voltage potential as VSS2. As discussed above, VDD1 plane 560 and VDD2 plane 562 may be coupled by back-to back diodes (or series of back-to-back diodes). In such cases, VDD1 will not deviate from VDD2 more than a diode drop (or multiple diode drops where multiple diodes are used in series). Similarly, VSS1 plane 566 and VSS2 plane 564 may be coupled by back-to back diodes (or series of back-to-back diodes). In such cases, VSS1 will not deviate from VSS2 more than a diode drop (or multiple diode drops where multiple diodes are used in series). As used herein, the phrases “maintained at approximately the same voltage” “maintained at approximately the same potential” are used in the broadest sense to mean maintenance within the voltage difference supportable by a plane coupling circuit between the potential planes. Thus, for example, where planes are coupled using back-to-back diodes, the planes are maintained at approximately the same voltage when there is less than a diode drop between the different potentials. It should be noted that the approximate values are measured when the device is operating as intended (i.e., normal operation), and is not necessarily effective when the device is being subjected to a test, such as a CDM test. Also, it should be noted that in other cases where circuit 500 is operational, VDD1 may be maintained at a voltage level different from that of VDD2, and VSS1 may be maintained at a voltage level different from that of VSS2.

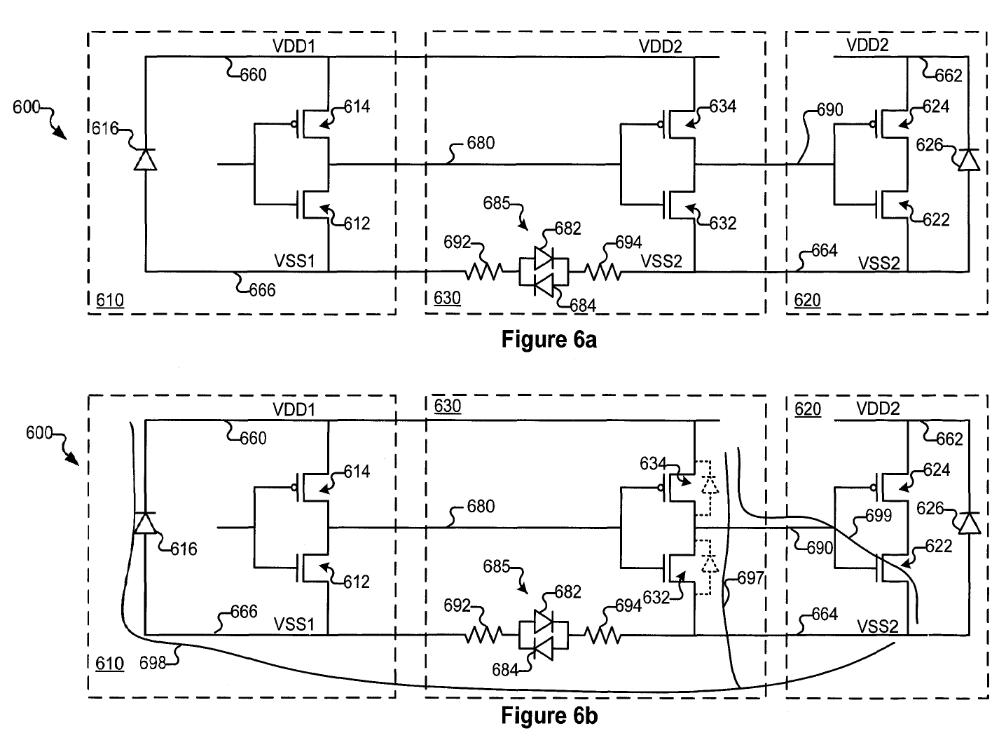

Turning to FIG. 6, an exemplary circuit 600 powered using cross-accessed power planes in accordance with various embodiments of the present invention is depicted. In particular, circuit 600 includes a drive circuit 610 that is powered by a differential between a pair of potential planes, including a VDD1 plane 660 and a VSS1 plane 666. As shown, when circuit 600 is operational, potential plane 660 is driven to a voltage level defined as VDD and potential plane 666 is driven to a voltage level defined as VSS. Circuit 600 also includes a receive circuit 620 that is powered by a differential between a pair of potential planes, including a VDD2 plane 662 and a VSS2 plane 664. Potential plane 662 is driven to a voltage level defined as VDD and potential plane 664 is driven to a voltage level defined as VSS. Circuit 600 also includes a transitional circuit 630 that is powered by a differential between potential plane 660 and potential plane 664. Of note, exemplary circuit 600 is similar to the previously described exemplary circuit 500 except that transitional circuit 630 cross-accesses different potential planes. Each of the pairs of potential planes (i.e., VSS1/VDD1 and VSS2/VDD2) are referred to as domains.

Drive circuit 610 drives a signal output 680 to transitional circuit 630, and transitional circuit 630 drives a signal input 690 to receive circuit 620. In this way, inter-domain signaling from drive circuit 610 to receive circuit 620 is electrically coupled via transitional circuit 630 that cross-accesses the potential planes. Thus, an inter domain signal that would have traditionally been connected directly between drive circuit 610 and receive circuit 620 (see e.g., FIG. 3 above) is connected by a transitional circuit 630 that is cross-domain (i.e., a circuit that is powered by one potential plane from one domain, and another potential plane in another domain).

Circuit 600 further includes a plane coupling circuit 685 that electrically couples VSS1 plane 666 to VSS2 plane 664. As shown, plane coupling circuit 685 includes back-to-back diodes 682, 684 and resistances 692, 694. In most cases, resistances 692, 694 represent the routing resistance and are modifiable by adjusting any floor planning that is done in the layout of circuit 600. It should be noted that in some cases a circuit similar to plane coupling circuit 685 may be used to couple VDD1 plane 660 to VDD2 plane 662 either in addition to plane coupling circuit 685 or in place of plane coupling circuit 685.

FIG. 6b shows three possible paths 697, 698, 699 through which an electrostatic discharge may take place when a pin associated with VDD1 plane 660 is grounded after a voltage is induced on nodes of circuit 600 during a CDM test. Path 698 moves current from VSS2 plane 664 to VDD1 plane 660 via resistances 692, 694, back-to-back diode 684 and diode 616, which is in reverse bias during normal operation of circuit 600. Diode 616 may be referred to as “reverse bias diode” 616. Again, as used herein, the phrase “reverse bias diode” indicates the bias on the diode when the associated circuit is in normal operation and does not indicate a bias relative to an electrostatic discharge path. Path 697 moves current from VSS2 plane 664 to VDD1 plane 660 via the parasitic diode of transistor 632 and the parasitic diode of transistor 634. In contrast, path 699 moves current from VSS2 plane 664 to VDD1 plane 660 via the gate oxide of transistor 622, and the parasitic diode of transistor 634. As will be appreciated by one of ordinary skill in the art, passing current along path 699 results in damage to circuit 600, while passing a reasonable current along path 697 and/or path 698 does not result in damage to circuit 600. Where the effective resistance of path 697 or path 698 is less than that of path 699, circuit 600 is protected from damage. In this case, the effective resistance of each of the paths is set forth in the following equations:

R_{Path 697}=R_{Diode 634}+R_{Diode 632}+R_{Routing697}, where R_{Routing697} represents all routing resistance along path 697;

R_{Path 698}=R₆₉₂+R₆₉₄+R_{Diode 684}+R_{Diode 616}, where R₆₉₂+R₆₉₄ represents all routing resistance along path 698; and

R_{Path 699}=R_{Gate Oxide 622}+R_{Diode 634}+R_{Routing699}, where R_{Routing699} represents all routing resistance along path 699; and

Transistor 632 and transistor 634 cannot sustain a high current along path 697 before damage will occur, but a current in the milliamp range may be sustained along path 697. To avoid an excessive current along path 697, routing resistances 692, 694 should be controlled such that current is discharged along path 698 in addition to that current discharged along path 697. However, as path 697 can sustain a current in the milliamp range before any damage is incurred and path 699 may only be able to sustain a current in the microamp range before damage will occur to the gate oxide of transistor 622, adding path 697 makes the design of routing resistances 692, 694 less complicated than that required where path 697 is not included. Said another way, where the parasitic diode of transistor 632 is in parallel with the gate oxide of transistor 622, a less resistive path is offered through the combination of one or both of paths 697, 698 than through path 699. Thus, the gate oxide of transistor 699 is protected during a CDM test.

In some cases, when circuit 600 is operational (i.e., powered in a normal operational mode), VDD1 is maintained to a voltage potential that is approximately the same as VDD2. Similarly, VSS1 may be maintained at the same voltage potential as VSS2. As discussed above, VDD1 plane 660 and VDD2 plane 662 may be coupled by back-to back diodes (or series of back-to-back diodes). In such cases, VDD1 will not deviate from VDD2 more than a diode drop (or multiple diode drops where multiple diodes are used in series). Similarly, VSS1 plane 666 and VSS2 plane 664 may be coupled by back-to back diodes (or series of back-to-back diodes). In such cases, VSS1 will not deviate from VSS2 more than a diode drop (or multiple diode drops where multiple diodes are used in series). As used herein, the phrases “maintained at approximately the same voltage” “maintained at approximately the same potential” are used in the broadest sense to mean maintenance within the voltage difference supportable by a plane coupling circuit between the potential planes. Thus, for example, where planes are coupled using back-to-back diodes, the planes are maintained at approximately the same voltage when there is less than a diode drop between the different potentials. It should be noted that the approximate values are measured when the device is operating as intended (i.e., normal operation), and is not necessarily effective when the device is being subjected to a test, such as a CDM test. Also, it should be noted that in other cases where circuit 600 is operational, VDD1 may be maintained at a voltage level different from that of VDD2, and VSS1 may be maintained at a voltage level different from that of VSS2.

In conclusion, the present invention provides novel systems, devices, methods and arrangements for limiting the effects of electrostatic discharge. While detailed descriptions of one or more embodiments of the invention have been given above, various alternatives, modifications, and equivalents will be apparent to those skilled in the art without varying from the spirit of the invention. For example, each of FIGS. 5-6 show the various circuits as comprising inverters, however, other circuitry may be used in addition to or in place of such inverters. Therefore, the above description should not be taken as limiting the scope of the invention, which is defined by the appended claims.

What is claimed is:

1. A system for reducing the effects of electrostatic discharge, the system comprising:
a first circuit, wherein the first circuit is powered by a differential between a first potential plane and a second potential plane;
a second circuit, wherein the second circuit is powered by a differential between a third potential plane and a fourth potential plane; and
a transitional circuit, wherein the transitional circuit receives a signal output from the first circuit and provides a signal input to the second circuit, and wherein the transitional circuit is powered by a differential between the first potential plane and the fourth potential plane.

2. The system of claim 1, wherein the first potential plane is a power plane, and wherein the fourth potential plane is a ground plane.

3. The system of claim 1, wherein the first potential plane is a ground plane, and wherein the fourth potential plane is a power plane.

4. The system of claim 1, wherein the first potential plane is a VDD plane, and wherein the fourth potential plane is a VSS plane.

5. The system of claim 1, wherein the first potential plane is a VSS plane, and wherein the fourth potential plane is a VDD plane.

6. The system of claim 1, wherein the first potential plane and the third potential plane are each distinct power planes maintained at approximately the same voltage level during normal operation of the system, and wherein the second potential plane and the fourth potential plane are distinct power planes maintained at approximately the same voltage level during normal operation of the system.

7. The system of claim 1, wherein the system further comprises:
a plane coupling circuit between at least one of the pair of the first potential plane and the third potential plane, and the pair of the second potential plane and the fourth potential plane.

8. The system of claim 7, wherein the plane coupling circuit includes a pair of back-to-back diodes.

9. The system of claim 8, wherein the system further includes a first reverse biased diode electrically coupled between the first potential plane and the second potential plane, and a second reverse biased diode electrically coupled between the third potential plane and the fourth potential plane.

10. The system of claim 1, wherein the first potential plane is a first VDD plane, wherein the second potential plane is a first VSS plane, wherein the third potential plane is a second VDD plane, wherein the fourth potential plane is a second VSS plane, and wherein:
the transitional circuit includes a P-type transistor and an N-type transistor, wherein the gate of the P-type transistor and the gate of the N-type transistor are electrically coupled to the signal output, wherein a first input of the P-type transistor is electrically coupled to the second VDD plane, wherein a second input of the P-type transistor is electrically coupled to a first input of the N-type transistor, wherein a second input of the N-type transistor is electrically coupled to the first VSS plane, and wherein the second input of the P-type transistor and the first input of the N-type transistor are electrically coupled to the signal output.

11. The system of claim 10, wherein the first VDD plane and the second VDD plane are maintained at approximately the same voltage level during normal operation of the system, and wherein the first VSS plane and the second VSS plane are maintained at approximately the same voltage level during normal operation of the system.

12. The system of claim 1, wherein the first potential plane is a first VDD plane, wherein the second potential plane is a first VSS plane, wherein the third potential plane is a second VDD plane, wherein the fourth potential plane is a second VSS plane, and wherein:
the transitional circuit includes a P-type transistor and an N-type transistor, wherein the gate of the P-type transistor and the gate of the N-type transistor are electrically coupled to the signal output, wherein a first input of the P-type transistor is electrically coupled to the first VDD plane, wherein a second input of the P-type transistor is electrically coupled to a first input of the N-type transistor, wherein a second input of the N-type transistor is electrically coupled to the second VSS plane, and wherein the second input of the P-type transistor and the first input of the N-type transistor are electrically coupled to the signal output.

13. The system of claim 11, wherein the first VDD plane and the second VDD plane are maintained at approximately the same voltage level during normal operation of the system, and wherein the first VSS plane and the second VSS plane are maintained at approximately the same voltage level during normal operation of the system.

14. A method for electrostatic discharge testing of a semiconductor device, the method comprising:
providing a semiconductor device, wherein the semiconductor device includes at least a first pin and a second pin, and wherein the semiconductor device includes:
a first circuit, wherein the first circuit is powered by a differential between a first potential plane and a second potential plane;
a second circuit, wherein the second circuit is powered by a differential between a third potential plane and a fourth potential plane;
a transitional circuit, wherein the transitional circuit receives a signal output from the first circuit and provides a signal input to the second circuit, and wherein the transitional circuit is powered by a differential between the first potential plane and the fourth potential plane;
a plane coupling circuit electrically coupled between the first potential plane and the third potential plane, wherein the plane coupling circuit includes a pair of back-to-back diodes; and
a reverse biased diode electrically coupled between the first potential plane and the second potential plane;
inducing a voltage potential on each of the first potential plane, the second potential plane, the third potential plane, and the fourth potential plane;
grounding one of the first pin and the second pin, wherein an electrically conductive path is established between the fourth potential plane and the first potential plane.

15. The method of claim 14, wherein the method further comprises:
failing the semiconductor device where the electrically conductive path includes traversing the signal input.

16. The method of claim 14, wherein the method further comprises:
passing the semiconductor device where the electrically conductive path avoids traversing the signal input.

17. The method of claim 14, wherein the electrically coupled path avoids the signal input, and wherein the electrically coupled path includes the plane coupling circuit and the reverse biased diode.

18. A electrostatic discharge resistant circuit, the circuit comprising:
a first group of transistors, wherein the first group of transistors is powered by a differential between a first potential plane and a second potential plane;
a second group of transistors, wherein the second group of transistors is powered by a differential between a third potential plane and a fourth potential plane;
a transitional group of transistors, wherein the transitional group of transistors receives a signal output from the first group of transistors and provides a signal input to the second group of transistors, and wherein the transitional group of transistors is powered by a differential between the first potential plane and the fourth potential plane;
a plane coupling circuit electrically coupled between one of the pair of the first potential plane and the third potential plane, and the pair of the second potential plane and the fourth potential plane, wherein plane coupling circuit include a pair of back-to-back diodes;
a first reverse biased diode electrically coupled between the first potential plane and the second potential plane; and
a second reverse biased diode electrically coupled between the third potential plane and the fourth potential plane.

19. The circuit of claim 18, wherein the first potential plane and the third potential plane are each distinct power planes maintained at approximately the same voltage level during normal operation of the system, and wherein the second potential plane and the fourth potential plane are distinct power planes maintained at approximately the same voltage level during normal operation of the system.

20. The circuit of claim 19, wherein the first potential plane is a first VDD plane and the third potential plane is a second VDD plane, and wherein the second potential plane is a first VSS plane and the fourth potential plane is a second VSS plane.
